(19) United States
(12) Patent Application Publication
(10) Pub. No.: US 2026/0129939 A1
(43) Pub. Date: May 7, 2026

(54) LDMOS TRANSISTOR WITH SPLIT GATE FIELD PLATE TAPERED TOWARD DRAIN REGION AND RELATED METHOD

(71) Applicant: GlobalFoundries Singapore Pte. Ltd., Singapore (SG)

(72) Inventor: Guowei Zhang, Singapore (SG)

(21) Appl. No.: 18/938,492

(22) Filed: Nov. 6, 2024

(51) Int. Cl. H01L 29/40; H01L 29/66; H01L 29/78

(52) U.S. Cl. CPC H10D 64/111; H10D 30/0281; H10D 30/65; H10D 64/01

(57) ABSTRACT

An LDMOS transistor includes a semiconductor substrate, a channel gate over the semiconductor substrate, a source region to a first side of the channel gate, and a drain region to a second, opposite side of the channel gate. The LDMOS transistor also includes a split gate field plate over the semiconductor substrate where the split gate field plate has a tapered surface that is thinner toward the drain region. In certain embodiments, the split gate field plate has no lateral overlap with the channel gate and an L-shaped gate dielectric separates the split gate field plate from the channel gate and the semiconductor substrate. The split gate field plate can be shorted to the source region to reduce gate-to-drain region (Miller) parasitic capacitance. The LDMOS transistor split gate field plate can be formed with no additional masks.

### BACKGROUND

The present disclosure relates to transistors, and more specifically, to a laterally diffused metal oxide semiconductor (LDMOS) transistor with a split gate field plate tapered toward a drain region of the transistor, and a related method.

Laterally diffused metal oxide semiconductor (LDMOS) transistors are used in, for example, radio frequency (RF) devices. LDMOS transistors include, within a semiconductor substrate such as a fin or a bulk substrate, and for an NFET device, a p-well with a source region therein and an n-well with a drain region therein. A channel gate extends over the p-well and n-well with the channel in the p-well and a drain extension region (also referred to in the art as a drain drift region) in the n-well. One challenge with these devices is continuing to reduce size and improve performance, e.g., with lower on resistance (R_{dson}) and lower parasitic capacitance.

### SUMMARY

All aspects, examples and features mentioned below can be combined in any technically possible way.

An aspect of the disclosure provides a laterally-diffused metal-oxide semiconductor (LDMOS) transistor, comprising: a semiconductor substrate; a channel gate over the semiconductor substrate; a source region to a first side of the channel gate; a drain region to a second, opposite side of the channel gate; and a split gate field plate over the semiconductor substrate, wherein the split gate field plate has a tapered surface that is thinner toward the drain region.

An aspect of the disclosure provides a laterally-diffused metal-oxide semiconductor (LDMOS) transistor, comprising: a semiconductor substrate; a channel gate in the semiconductor substrate; a source region to a first side of the channel gate; a drain region to a second, opposite side of the channel gate; a split gate field plate over the semiconductor substrate, wherein the split gate field plate over the semiconductor substrate, wherein the split gate field plate is spaced apart from the channel gate, has no lateral overlap with the channel gate and has a tapered surface that is thinner toward the drain region; and an L-shaped gate dielectric separating the split gate field plate from the channel gate and the semiconductor substrate.

An aspect of the disclosure provides a method comprising: forming a channel gate including a first polysilicon gate body layer over a first gate dielectric layer over a semiconductor substrate, wherein the first polysilicon gate body layer has an end over the first gate dielectric layer; forming a second gate dielectric layer over the end of the first polysilicon gate body layer, wherein the second gate dielectric layer is thicker than the first gate dielectric layer; forming a second polysilicon gate body layer over the second gate dielectric layer over the end of the first polysilicon gate body layer; forming a split gate field plate from the second polysilicon gate body layer over the second gate dielectric layer over the end of the first polysilicon gate body layer; and forming a source region and a drain region configured for a laterally-diffused metal-oxide semiconductor (LDMOS) transistor in the semiconductor substrate, wherein the split gate field plate has a tapered surface that is thinner toward the drain region.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIGS. 1A-B show cross-sectional views of a preliminary structure according to embodiments of the disclosure;

FIGS. 2A-B show cross-sectional views of forming a doping region in a semiconductor substrate, according to embodiments of the disclosure;

FIGS. 3A-B show cross-sectional views of forming a dielectric layer and a polysilicon gate body layer, according to embodiments of the disclosure;

FIGS. 4A-B show cross-sectional views of forming a channel gate and a split gate field plate, according to embodiments of the disclosure;

FIGS. 5A-B show cross-sectional views of forming source/drain regions, according to embodiments of the disclosure;

FIGS. 6A-B show cross-sectional views of a laterally diffused metal oxide semiconductor (LDMOS) transistor, according to embodiments of the disclosure;

FIG. 7 shows a cross-sectional view of an LDMOS transistor, according to other embodiments of the disclosure;

FIG. 8 shows a cross-sectional view of an LDMOS transistor, according to yet other embodiments of the disclosure;

FIG. 9 shows an enlarged cross-sectional view of a split gate field plate, according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure include a laterally diffused metal-oxide semiconductor (LDMOS) transistor, and a related method. The LDMOS transistor includes a semiconductor substrate, a channel gate over the semiconductor substrate, a source region to a first side of the channel gate, and a drain region to a second, opposite side of the channel gate. The LDMOS transistor also includes a split gate field plate over the semiconductor substrate where the split gate field plate has a tapered surface that is thinner toward the drain region. In certain embodiments, the split gate field plate has no lateral overlap with the channel gate and an L-shaped gate dielectric separates the split gate field plate from the channel gate and the semiconductor substrate. Conventional LDMOS transistors have a split gate field plate having a thicker gate dielectric layer than the channel gate, which is formed by a non-self-aligned dielectric formation technique, e.g., high temperature oxide (HTO) patterning. The lateral accuracy of the thicker gate dielectric layer is limited by the lithography critical dimension and overlay accuracy. The LDMOS transistor according to embodiments of the disclosure has a thicker gate dielectric layer for the split gate field plate formed using a self-aligned formation technique with precision control of its size. In certain embodiments, the split gate field plate can be shorted to the source region to reduce gate-to-drain region (Miller) parasitic capacitance. The split gate field plate can be formed with no extra costs, e.g., with no additional masks.

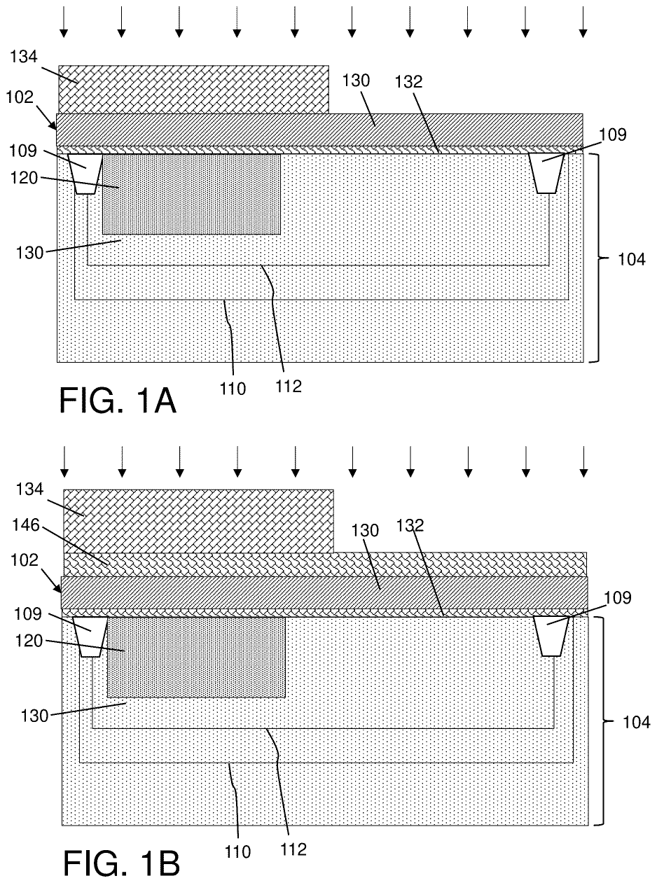

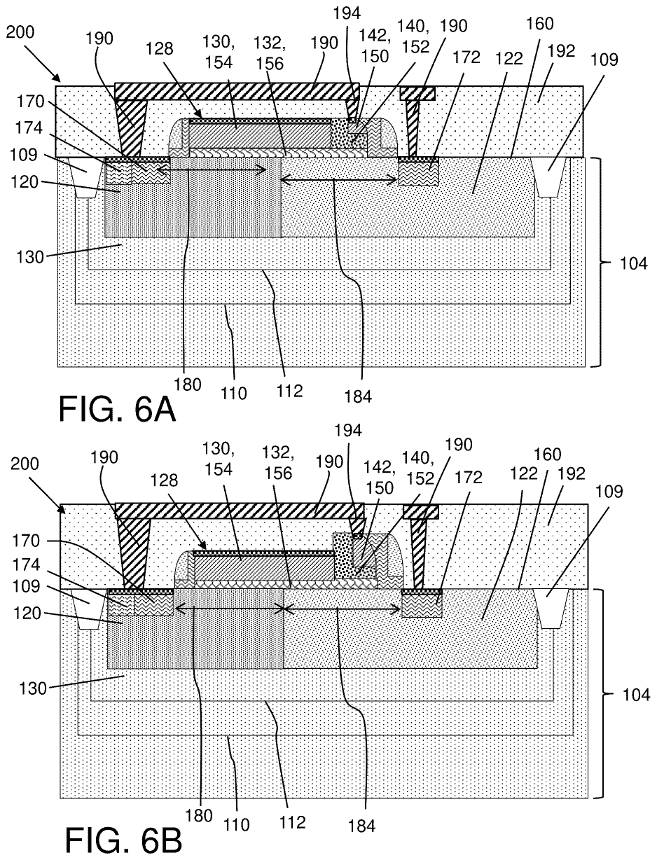

FIGS. 1A-8 show cross-sectional views of a method to form a laterally diffused metal-oxide LDMOS transistor 200 (FIGS. 6A-B, 7, 8) according to various embodiments of the disclosure. For purposes of description, LDMOS transistor 200 (FIGS. 6A-B, 7, 8) may be implemented as a FinFET, but it is emphasized that it can also be applied in other types of MOS devices, e.g., bulk, planar semiconductor substrates. As will be described herein, the ‘A’ labeled drawings show cross-sectional views according to certain embodiments, and the ‘B’ labeled drawings show cross-sectional views according to other embodiments.

FIGS. 1A-B show cross-sectional views of a preliminary structure 102 configured for forming LDMOS transistor 200 (FIGS. 6A, 7, 8). Preliminary structure 102 includes a semiconductor substrate 104. Semiconductor substrate 104 may be formed using any now known or later developed technology, e.g., with a semiconductor fin or bulk semiconductor. Semiconductor substrate 104 may include but is not limited to silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entire semiconductor substrate may be strained. In certain embodiments, semiconductor substrate 104 may include a p-type dopant, which may include but is not limited to: boron (B), indium (In) and gallium (Ga). P-type dopants are elements introduced to semiconductor material to generate a free hole by “accepting” electron from semiconductor atom and “releasing” the hole at the same time. The dopant may be introduced to semiconductor substrate 104 in any now known or later developed fashion, e.g., in-situ doping during formation or ion implanting. As the doping technology used in this setting is well known in the art, no further detail is required.

Preliminary structure 102 may also include any now known or later developed trench isolation 109 in substrate 104 to electrically isolate the eventually formed LDMOS transistor 200 (FIGS. 6A-B, 7, 8) from other devices. As the techniques to form trench isolations 109 are well known no further details are required for understanding.

Preliminary structure 102 may also include a plurality of doped wells 110, 112 in semiconductor substrate 104. For purposes of description, doped wells 110, 112 include but are not limited to an n-type doped well (hereafter “n-well”) 110 surrounding a p-typed doped well (hereafter “p-well”) 112. Preliminary structure 102 formation also includes forming doped region 120. Doped region 120 may take the form of a p-type doped well. Doped region 120 will be referenced as a region to differentiate from p-well 112; it is recognized that both are doped wells. N-well 110, p-well 112 and doped region 120 may be formed using any now known or later developed semiconductor doping technique. For example, n-well 110, p-well 112 and doped region 120 may be formed by mask-directed doping by ion implantation followed by an anneal to drive in the dopants, in-situ doping during formation of substrate 104, and/or any other now known or later developed doping process. As noted, n-well 110 may be doped with an n-type dopant. N-type dopants may include but are not limited to: phosphorous (P), arsenic (As), or antimony (Sb). N-type is an element introduced to semiconductor to generate free electrons by “donating” electrons to the semiconductor. P-well 112 and doped region 120 may be doped with a p-type dopant. The p-type dopant of p-well 112 may be the same as semiconductor substrate 104, but with a higher dopant concentration. The p-type dopant of doped region 120 may be the same as p-well 112 and/or semiconductor substrate 104, but with a higher dopant concentration. Alternatively, the p-type dopants of each structure may be different.

FIG. 1A-B also shows forming a first polysilicon gate body layer 130 over a first gate dielectric layer 132 over semiconductor substrate 104. That is, preliminary structure 102 may also include first polysilicon gate body layer 130 over first gate dielectric layer 132 over semiconductor substrate 104. First gate dielectric layer 132 may include any now known or later developed gate dielectric appropriate for an LDMOS transistor including but not limited to: silicon oxide, hafnium silicate, hafnium oxide, zirconium silicate, zirconium oxide, silicon nitride, silicon oxynitride, high-k material or any combination of these materials. First gate dielectric layer 132 may be formed using any now known or later developed semiconductor fabrication technique, e.g., deposition. “Depositing” may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation. In one example, tetraethyl orthosilicate (TEOS) based ALD may be used to form silicon oxide. In certain embodiments, as shown in FIG. 1A-B, forming first gate dielectric layer 132 includes forming the layer with a uniform thickness. First gate dielectric layer 132 may have any desired thickness for a gate channel 180 (see e.g., FIGS. 6A-B) to be formed thereunder in semiconductor substrate 104.

First polysilicon gate body layer 130 may include any now known or later developed polysilicon material appropriate for a gate body in an LDMOS transistor, i.e., a channel gate or a split gate field plate. First polysilicon gate body layer 130 may be formed by any appropriate deposition technique, e.g., ALD.

FIG. 1B, in contrast to FIG. 1A, also shows optionally forming a dummy gate dielectric layer 146 over first polysilicon gate body layer 130. Dummy gate dielectric layer 146 can be thicker than first gate dielectric layer 132. As will be described further, the thickness of dummy gate dielectric layer 146 can be selected to control a height and/or width of split gate field plate 150 (FIG. 6B), e.g., to improve spacing for landing of contacts thereon. Dummy gate dielectric layer 146 can include any of the materials listed herein for first gate dielectric layer 132 and may be formed using any appropriate deposition technique listed herein appropriate for the material used.

It will be recognized that preliminary structure 102, as shown in FIGS. 1A-B, is arranged to form LDMOS transistor 200 (FIGS. 6A-B, 7, 8) with a split gate field plate 150 (FIGS. 6A-B, 7, 8) (also known as a floating gate). Other forms of LDMOS transistors may include an additional trench isolation (not shown) in a drain extension region 184 (FIGS. 6A-B, 7, 8) of LDMOS transistor 200 (FIGS. 6A-B, 7, 8).

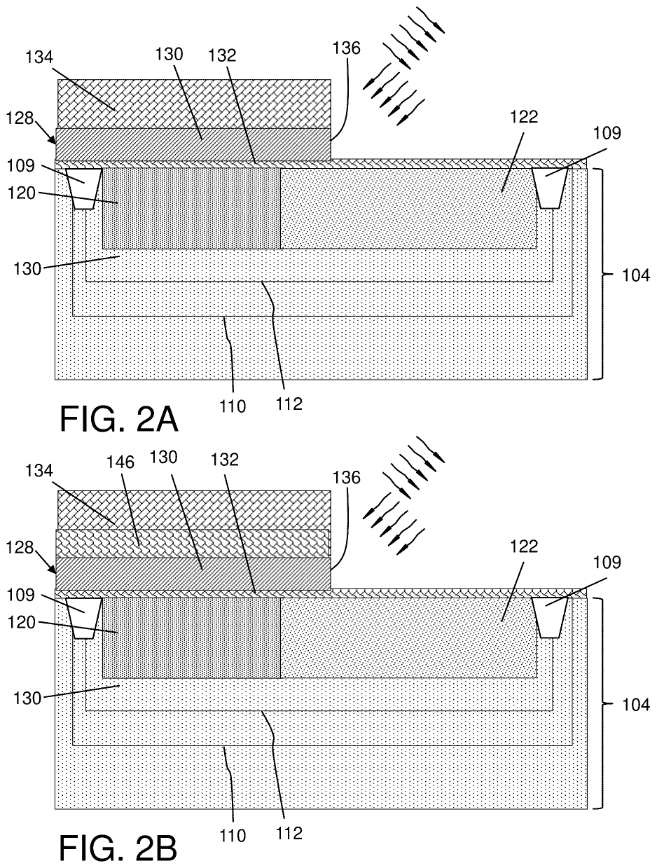

FIGS. 1A-B also show cross-sectional views of first steps of forming (part of) a channel gate 128 (FIGS. 2A-B) including first polysilicon gate body layer 130 over first gate dielectric layer 132 over semiconductor substrate 104. FIG. 1A shows patterning a mask 134 over an area in which channel gate 128 is desired and etching (as indicated by vertical arrows in FIG. 1A) first polysilicon gate body layer 130, stopping on first gate dielectric layer 132. FIG. 1B shows patterning mask 134 over an area in which channel gate 128 is desired and etching (as indicated by vertical arrows in FIG. 1B) first polysilicon gate body layer 130 and dummy gate dielectric layer 146, stopping on first gate dielectric layer 132. In other embodiments, not shown, first gate dielectric layer 132 may be removed from over semiconductor substrate 104 at this stage. That is, the etching may remove first gate dielectric layer 132 from over semiconductor substrate 104, leaving it under first polysilicon gate body layer 130. There are generally two categories of etching, (i) wet etch and (ii) dry etch. Wet etch is performed with a solvent (such as an acid) which may be chosen for its ability to selectively dissolve a given material (such as oxide), while, leaving another material (such as polysilicon) relatively intact. This ability to selectively etch given materials is fundamental to many semiconductor fabrication processes. A wet etch will generally etch a homogeneous material (e.g., oxide) isotropically, but a wet etch may also etch single-crystal materials (e.g. silicon wafers) anisotropically. Dry etch may be performed using a plasma. Plasma systems can operate in several modes by adjusting the parameters of the plasma. Ordinary plasma etching produces energetic free radicals, neutrally charged, that react at the surface of the wafer. Since neutral particles attack the wafer from all angles, this process is isotropic. Ion milling, or sputter etching, bombards the wafer with energetic ions of noble gases, which approach the wafer approximately from one direction, and therefore this process is highly anisotropic. Reactive-ion etching (RIE) operates under conditions intermediate between sputter and plasma etching and may be used to produce deep, narrow features, such as STI trenches. Here, a RIE may be used to remove first polysilicon gate body layer 130 and, where provided (see FIG. 1B), dummy gate dielectric layer 146.

After the etching, as shown in FIGS. 2A-B, first polysilicon gate body layer 130 (and, where provided, dummy gate dielectric layer 146) has an end 136 over first gate dielectric layer 132. A right-side extent, as shown, of channel gate 128 can be user defined based on mask 134 configuration. As will be further described, an additional patterning step may be optionally used to define a left-side extent of channel gate 128.

FIGS. 2A-B show cross-sectional views of forming a doped region 122 adjacent doped region 120 in substrate 104. More particularly, FIGS. 2A-B show forming doped region 122 using mask 134. Doped region 122 may take the form of an n-type doped well. Doped region 122 will be referenced as a region to differentiate from n-well 110; it is recognized that both are doped wells. Doped region 122 may be formed using any now known or later developed semiconductor fabrication technique. For example, doped region 122 may be formed using an angled mask-directed ion implantation (indicated by curved arrows in FIGS. 2A-B) followed by an anneal to drive in the dopants. Doped region 122 may include any of the n-type dopants listed for n-well 110. Doped region 122 may include a higher concentration of n-type dopants than n-well 110. Once complete, mask 134 may be removed using any known removal process appropriate for the mask material, e.g., a wet etch for hard nitride mask or an ashing process (oxygen dry strip process) for a soft resist-based mask.

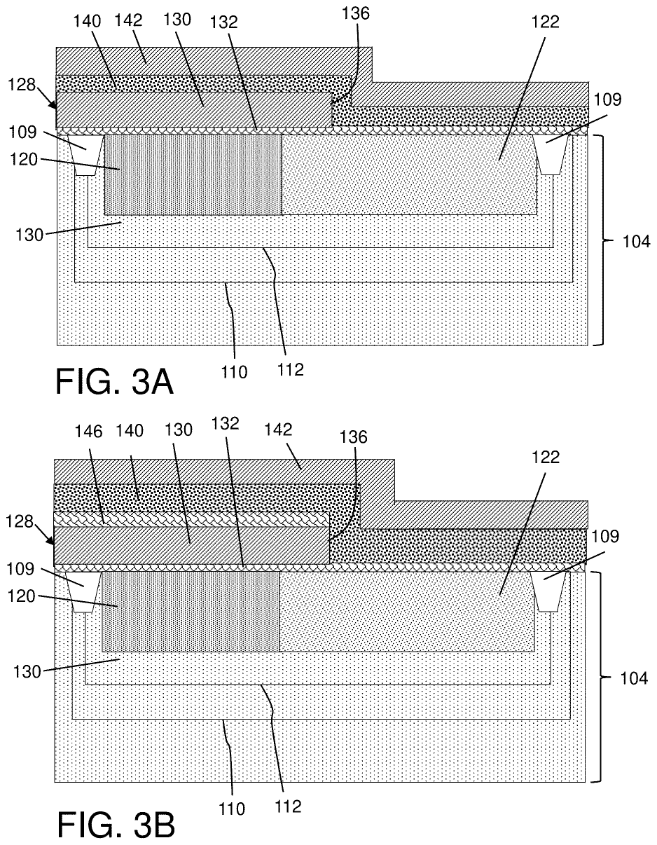

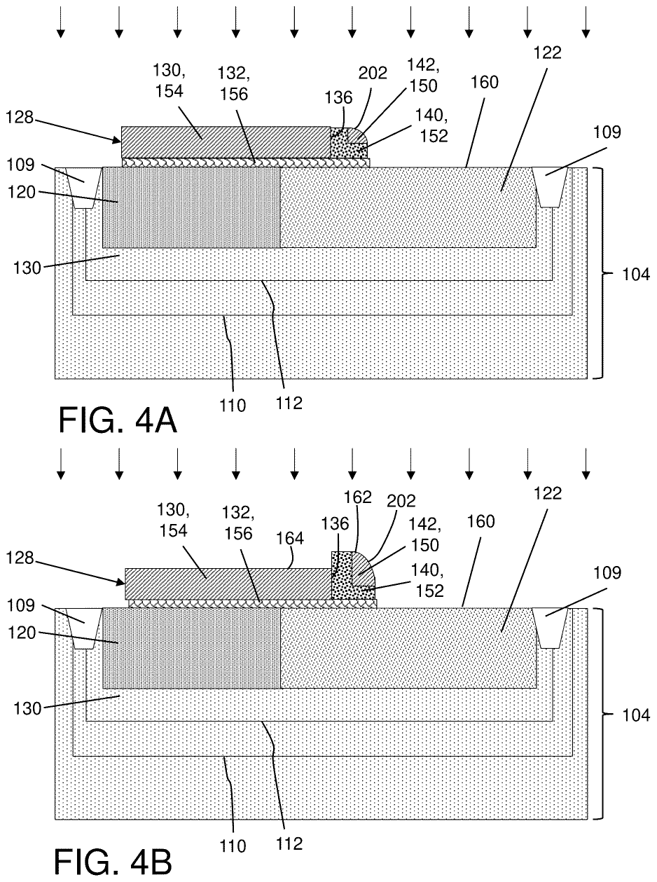

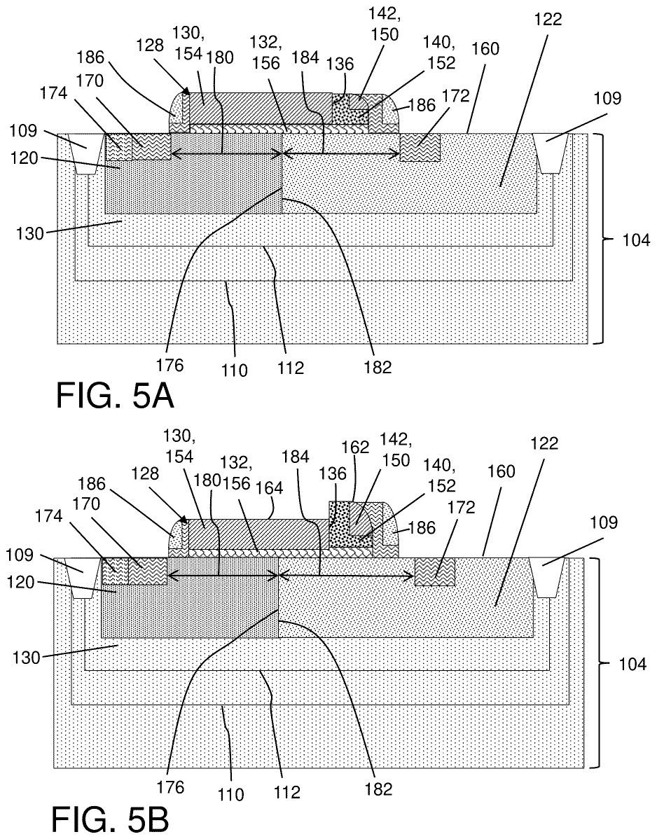

FIGS. 3A-4B show cross-sectional views of forming a split gate field plate 150 (FIGS. 5A-B). FIGS. 3A-B show forming a second polysilicon gate body layer 142 over a second gate dielectric layer 140 over end 136 of first polysilicon gate body layer 130 (and, where provided as shown in FIG. 3B, dummy gate dielectric layer 146). In FIG. 3A, second gate dielectric layer 140 is formed directly over first polysilicon gate body layer 130 and first gate dielectric layer 132, and in FIG. 3B, second gate dielectric layer 140 is formed directly over dummy gate dielectric layer 146 and first gate dielectric layer 132. Second gate dielectric layer 140 can be thicker than first gate dielectric layer 132. As will be described further, the thickness of second gate dielectric layer 140 can be selected to control a thickness of split gate field plate 150 (FIGS. 5A-B) and a spacing of split gate field plate 150 (FIGS. 5A-B) from channel gate 128 and semiconductor substrate 104. Second gate dielectric layer 140 can include any of the materials listed herein for first gate dielectric layer 132 and may be formed using any appropriate deposition technique listed herein appropriate for the material used. Second polysilicon gate body layer 142 can include any of the materials listed herein for first polysilicon gate body layer 130 and may be formed using any appropriate deposition technique listed herein appropriate for the material used.

FIGS. 4A-B show cross-sectional views of forming a split gate field plate 150 from second polysilicon gate body layer 142 over second gate dielectric layer 140 over end 136 of first polysilicon gate body layer 130 based on the FIGS. 3A and 3B arrangements, respectively. Forming split gate field plate 150 may include a blanket etch (arrows), such as a RIE. Other etching processes are also possible. As illustrated, the etching removes second polysilicon gate body layer 142, except for a tapered portion thereof that provides split gate field plate 150. The etching also removes second gate dielectric layer 140 except under the remaining portion of second polysilicon gate body layer 142 that forms split gate field plate 150. In FIG. 4B, the etching may also remove dummy gate dielectric layer 146 from over first polysilicon gate body layer 130. Split gate field plate 150 has tapered surface 202 (see also FIG. 9) that is thinner on one end compared to the other. In the example point of view shown, split gate field plate 150 is thinner toward the right side than to the left side. The right side will eventually include a drain region 172 (FIGS. 5A-B). More particularly, split gate field plate 150 may have a shape similar to that of a spacer with a rounded, tapered edge.

Split gate field plate 150 is spaced apart from channel gate 128 and has no lateral overlap with channel gate 128. A distance between split gate field plate 150 and channel gate 128, i.e., end 136 thereof, is controlled by a thickness of second gate dielectric layer 140. Second gate dielectric layer 140 under split gate field plate 150 is now an L-shaped (gate) dielectric 152 separating split gate field plate 150 from channel gate 128 and semiconductor substrate 104. Channel gate 128 includes polysilicon gate body 154 (from first polysilicon gate body layer 130) and a gate dielectric 156 (from first gate dielectric layer 132) between polysilicon gate body 154 and semiconductor substrate 104. Hence, channel gate 128 and split gate field plate 150 each include a polysilicon gate body layer 130, 142 on a continuous planar surface 160 of semiconductor substrate 104. A lower portion, i.e., horizontal portion, of L-shaped dielectric 152 separates split gate field plate 150 from semiconductor substrate 104 and is thicker than gate dielectric 156 of channel gate 128. Similarly, a lateral distance separating split gate field plate 150 from channel gate 128, i.e., end 136 thereof, is identical to a thickness of an upper portion, i.e., vertical portion, of L-shaped dielectric 152. Split gate field plate 150 may be between channel gate 128 and drain region 172.

In FIG. 4B, due to the presence of dummy gate dielectric layer 146 (FIGS. 1B, 2B, 3B), an upper surface 162 of split gate field plate 150 may be higher than an upper surface 164 of channel gate 128. In addition, a width of split gate field plate 150 may be wider due to the presence of dummy gate dielectric layer 146, e.g., to improve space for landing of contacts thereon.

At this stage, an optional additional patterning (not shown) of channel gate 128, e.g., to define a left side extent thereof, may occur. However, this is not necessary in call cases where channel gate 128 already has the necessary shape, length, etc. More particularly, in certain embodiments, channel gate 128 may be further patterned, e.g., compared to previously illustrated versions, with doped region 122 covered by a mask (not shown) to protect it. During this process, first polysilicon gate body layer 130 may be trimmed (e.g., on left side) and first gate dielectric layer 132 may be removed, e.g., by etching, outside of first polysilicon gate body layer 130 of channel gate 128 and split gate field plate 150. Again, this step may not be necessary if channel gate 128 already has the desired shape, length, etc.

FIGS. 5A-B show cross-sectional views of forming, among other things, a source region 170 and a drain region 172 configured for LDMOS transistor 200 (FIGS. 6A-B, 7, 8) in semiconductor substrate 104. Conventional spacers 186 may be formed along sidewalls of channel gate 128 and split gate field plate 150. Spacers 186 may include any now known or later developed spacer material and may be formed with any now known or later developed process. Source/drain regions 170, 172 may be formed using any now known or later developed semiconductor doping technique. For example, source/drain regions 170, 172 may be formed by mask-directed doping by ion implantation (not shown) followed by an anneal to drive in the dopants. Spacers 186 may self-align source/drain regions 170, 172. Source/drain regions 170, 172 may be doped with any n-type dopant as described herein. Source region 170 may optionally also include an additional doped contact region 174. Doped contact region 174 may be p-type doped but with a higher concentration than doped region 120. Doped region 120 (e.g., a p-well) extends around source region 170 (with P+ doped contact region 174 and N+ doped region 172) in semiconductor substrate 104 and doped region 122 (n-well) extends around drain region 172 (N+ doped region) in semiconductor substrate 104, respectively.

As understood in the field, a space between source region 170 and an edge 176 of doped region 120 defines a channel region 180 of the device; and a space between an edge 182 of doped region (n-well) 122 and drain region 172 defines a drain extension 184 (also known as a drift region). While edges 176, 182 are shown as co-linear, that is not necessary in all instances.

It is understood that LDMOS transistor 200 may also be formed in a manner that two transistors share a single drain region 172 and doped region (n-well) 122. In this case, preliminary structure 102 would include another source region 170 and doped region 120 mirrored to the right of drain region 172.

FIGS. 6A-B, 7 and 8 show cross-sectional views of various subsequent processes to complete LDMOS transistor 200, such as forming interconnects 190 to source/drain regions 170, 172, channel gate 128 (interconnect located out of view) and split gate field plate 150. Any now known or later developed salicidation process may be performed on source/drain regions 170, 172, channel gate 128 and/or split gate field plate 150. Silicide may be formed using any now known or later developed technique, e.g., performing an in-situ pre-clean, depositing a metal such as titanium, nickel, cobalt, etc., annealing to have the metal react with silicon or polysilicon, and removing unreacted metal. Interconnects 190 can be formed using any now known or later developed techniques such as but not limited to depositing one or more interlayer dielectric (ILD) layers 192, forming openings for contacts and/or wires, depositing a refractory metal liner and conductor, and planarizing. ILD layers 192 may include any currently-known or later developed substance for providing electrical insulation, and as examples may include: silicon nitride (Si₃N₄), silicon oxide (SiO₂), fluorinated SiO₂ (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, a spin-on silicon-carbon containing polymer material, near frictionless carbon (NFC), or layers thereof. A contact 194 on split gate field plate 150 is over drain extension region 184 in semiconductor substrate 104 between channel gate 128 and drain region 172.

In certain embodiments, as shown in FIGS. 6A-B and 7, split gate field plate 150 may be electrically connected to source region 170, e.g., by interconnect(s) 190. Where this connection is provided, it reduces gate to drain capacitance to reduce parasitic capacitance. In other embodiments split gate field plate 150 may be electrically connected to channel gate 128 (not shown).

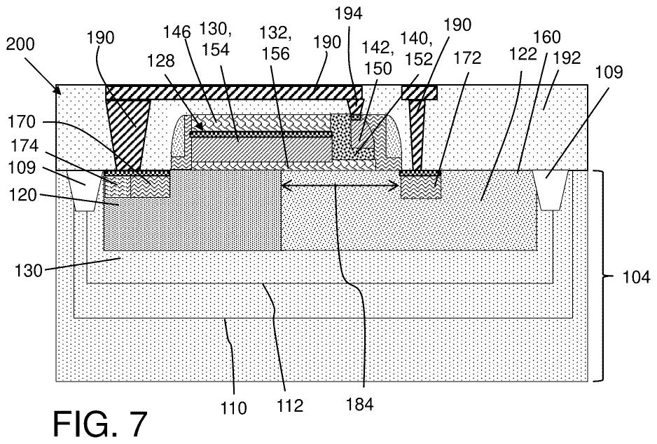

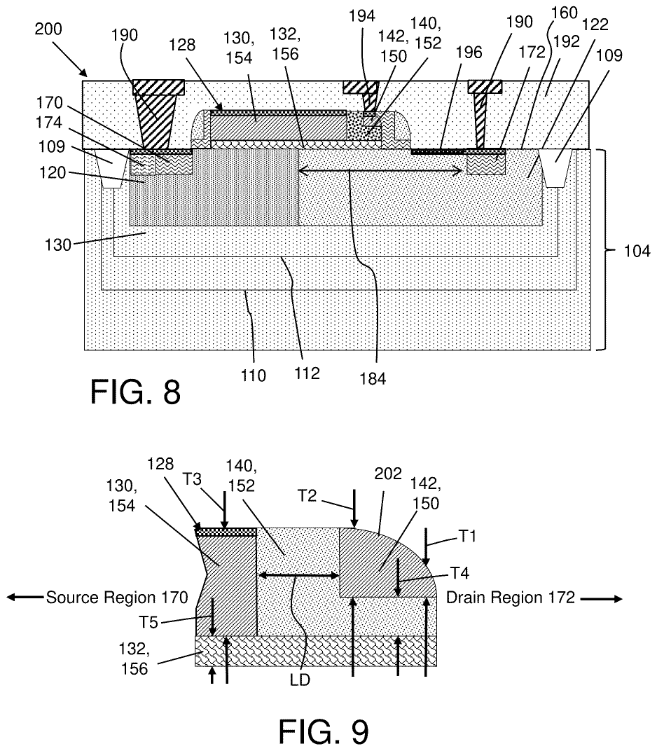

FIGS. 7-8 show cross-sectional view of alternative embodiments of LDMOS transistor 200.

FIG. 7 shows an embodiment in which dummy gate dielectric layer 146 remains over channel gate 128. To provide this embodiment, a mask (not shown) may be formed over channel gate 128 to protect dummy gate dielectric layer 146 from the etching provided in FIGS. 3B and 4B. FIG. 8 shows an embodiment in which a silicide blocking layer 196 is used to further extend drain extension 184 from channel gate 128 to, e.g., provide higher voltage devices. Silicide blocking layer 196 may include any now known or later developed material to prevent silicidation such as but not limited to a layer of oxide and/or nitride.

Referring to FIGS. 6A-9, embodiments of LDMOS transistor 200 will now be described. LDMOS transistor 200 includes semiconductor substrate 104, which may include, for example, a semiconductor fin or bulk semiconductor substrate. LDMOS transistor 200 also includes channel gate 128 over semiconductor substrate 104, source region 170 to a first side (left as illustrated) of channel gate 128, and drain region 172 to a second, opposite side (right as illustrated) of channel gate 128. LDMOS transistor 200 also includes split gate field plate 150 over semiconductor substrate 104. Channel gate 128 includes polysilicon gate body 154 and gate dielectric 156 between polysilicon gate body 154 and semiconductor substrate 104. Similarly, split gate field plate 150 includes polysilicon gate body (same reference label) and (L-shaped, gate) dielectric 152 between its polysilicon gate body and semiconductor substrate 104. Hence, channel gate 128 and split gate field plate 150 each include a polysilicon gate body 154 (and 150), respectively, over a continuous planar surface 160 of semiconductor substrate 104.

FIG. 9 shows an enlarged cross-sectional view of split gate field plate 150. Split gate field plate 150 has a tapered surface 202 that is thinner toward drain region 172. That is, split gate field plate 150 has a thickness T1 closer to drain region 172 (see, e.g., FIG. 9) that is thinner than a thickness T2 closer to source region 170 (see, e.g., FIG. 9). Split gate field plate 150 may have a shape similar to a spacer, but this is not necessary in all cases. In addition, polysilicon gate body 154 of channel gate 128 may be thicker than polysilicon gate body of split gate field plate 150—compare thickness T2 and T3 in FIG. 9. Split gate field plate 150 is also spaced apart from channel gate 128 by second gate dielectric layer 140 and has no lateral overlap with channel gate 128. More particularly, second gate dielectric layer 140 provides L-shaped gate dielectric 152 separating split gate field plate 150 from channel gate 128 and semiconductor substrate 104. A lower (horizontal) portion of L-shaped gate dielectric 152 separates split gate field plate 150 from semiconductor substrate 104 and is thicker than first gate dielectric layer 132 (i.e., gate dielectric 156) of channel gate 128—compare thickness T4 and T5. As shown in FIG. 9, a lateral distance LD separating split gate field plate 150 from channel gate 128 is identical to a thickness of the upper portion, i.e., vertical portion, of L-shaped gate dielectric 152.

In certain embodiments, as shown in FIGS. 6A-9, LDMOS transistor 200 may include contact 194 on split gate field plate 150. Contact 194 is over drain extension region 184 in semiconductor substrate 104 between channel gate 128 and drain region 172. In certain embodiments, as shown in FIGS. 6A-B and 7, split gate field plate 150 is electrically connected, i.e., shorted, to source region 170, which reduces gate-to-drain (Miller) parasitic capacitance. In other embodiments, not shown, split gate field plate 150 is electrically connected, i.e., shorted, to gate channel 128. In certain embodiments, as shown in FIG. 8, silicide blocking layer 196 may be provided on semiconductor substrate 104, i.e., an upper surface thereof, between split gate field plate 150 and drain region 172 to enlarge drain extension region 184.

In certain embodiments, as shown in FIG. 5B, upper surface 162 of split gate field plate 150 may be higher than upper surface 164 of channel gate 128, i.e., of polysilicon gate body 154 thereof. Although not necessary in all cases, where this arrangement is provided, it allows widening of upper surface 162 of split gate field plate 150 to provide larger area for landing of contact 194 (FIG. 7) thereon.

In other embodiments of the disclosure, LDMOS transistor 200 may include semiconductor substrate 104, which may include, for example, a semiconductor fin, bulk semiconductor substrate or other type of semiconductor substrate. LDMOS transistor 200 also includes channel gate 128 over semiconductor substrate 104, source region 170 to a first side (left as illustrated) of channel gate 128, and drain region 172 to a second, opposite side (right as illustrated) of channel gate 128. LDMOS transistor 200 also includes split gate field plate 150 over semiconductor substrate 104. Split gate field plate 150 is spaced apart from channel gate 128, has no lateral overlap with channel gate 128 and has, as shown in FIG. 9, a tapered surface 202 that is thinner toward drain region 172. LDMOS transistor 200 also includes L-shaped gate dielectric 152 separating split gate field plate 150 from channel gate 128 and semiconductor substrate 104.

While LDMOS transistor 200 has been described herein with a particular dopant configuration to form a certain polarity device, it will be recognized that the dopant configurations can be switched or otherwise modified to create a different polarity device or the same type polarity device but with different operational characteristics.

Embodiments of the disclosure provide various technical and commercial advantages, examples of which are discussed herein. For example, the LDMOS transistor includes a split gate field plate foreign a self-aligned manner with precision control of its size. In another example, the split gate field plate can be shorted to the source region to reduce gate-to-drain (Miller) parasitic capacitance. In addition, in another example, the split gate field plate can be formed with no extra costs, e.g., with no additional masks.

The structure and method as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A laterally-diffused metal-oxide semiconductor (LDMOS) transistor, comprising:
a semiconductor substrate;
a channel gate over the semiconductor substrate;
a source region to a first side of the channel gate;
a drain region to a second, opposite side of the channel gate; and
a split gate field plate over the semiconductor substrate, wherein the split gate field plate has a tapered surface that is thinner toward the drain region.

2. The LDMOS transistor of claim 1, wherein the split gate field plate is spaced apart from the channel gate and has no lateral overlap.

3. The LDMOS transistor of claim 1, further comprising an L-shaped gate dielectric separating the split gate field plate from the channel gate and the semiconductor substrate.

4. The LDMOS transistor of claim 3, wherein the channel gate includes a polysilicon gate body and a dielectric layer between the polysilicon gate body and the semiconductor substrate, wherein a lower portion of the L-shaped gate dielectric separating the split gate field plate from the semiconductor substrate is thicker than the dielectric layer of the channel gate.

5. The LDMOS transistor of claim 4, wherein a lateral distance separating the split gate field plate from the channel gate is identical to a thickness of an upper portion of the L-shaped gate dielectric.

6. The LDMOS transistor of claim 1, wherein the channel gate and the split gate field plate each include a polysilicon gate body over a continuous planar surface of the semiconductor substrate.

7. The LDMOS transistor of claim 1, further comprising a contact on the split gate field plate, the contact over a drain extension region in the semiconductor substrate between the channel gate and the drain region.

8. The LDMOS transistor of claim 1, wherein the split gate field plate is electrically connected to the source region.

9. The LDMOS transistor of claim 1, further comprising a silicide blocking layer on the semiconductor substrate between the split gate field plate and the drain region.

10. The LDMOS transistor of claim 1, wherein the channel gate and the split gate field plate each include a polysilicon gate body and a dielectric layer between the polysilicon gate body and the semiconductor substrate, and wherein the polysilicon gate body of the channel gate is thicker than the polysilicon gate body of the split gate field plate.

11. The LDMOS transistor of claim 1, wherein an upper surface of the split gate field plate is higher than an upper surface of the channel gate.

12. The LDMOS transistor of claim 11, further comprising a silicide blocking layer on the semiconductor substrate between the split gate field plate and the drain region.

13. A laterally-diffused metal-oxide semiconductor (LDMOS) transistor, comprising:
a semiconductor substrate;
a channel gate in the semiconductor substrate;
a source region to a first side of the channel gate;
a drain region to a second, opposite side of the channel gate;
a split gate field plate over the semiconductor substrate, wherein the split gate field plate is spaced apart from the channel gate, has no lateral overlap with the channel gate and has a tapered surface that is thinner toward the drain region; and
an L-shaped gate dielectric separating the split gate field plate from the channel gate and the semiconductor substrate.

14. The LDMOS transistor of claim 13, wherein the channel gate includes a polysilicon gate body and a gate dielectric between the polysilicon gate body and the semiconductor substrate, wherein a lower portion of the L-shaped gate dielectric separating the split gate field plate from the semiconductor substrate is thicker than the gate dielectric of the channel gate.

15. The LDMOS transistor of claim 13, wherein a lateral distance separating the split gate field plate from the channel gate is identical to a thickness of an upper portion of the L-shaped gate dielectric.

16. The LDMOS transistor of claim 13, wherein the split gate field plate is electrically connected to the source region.

17. The LDMOS transistor of claim 13, further comprising a silicide blocking layer on the semiconductor substrate between the split gate field plate and the drain region.

18. The LDMOS transistor of claim 13, wherein the channel gate and the split gate field plate each include a polysilicon gate body and a gate dielectric layer between the polysilicon gate body and the semiconductor substrate, and wherein the polysilicon gate body of the channel gate is thicker than the polysilicon gate body of the split gate field plate.

19. The LDMOS transistor of claim 13, wherein an upper surface of the split gate field plate is higher than an upper surface of the channel gate.

20. A method, comprising:
forming a channel gate including a first polysilicon gate body layer over a first gate dielectric layer over a semiconductor substrate, wherein the first polysilicon gate body layer has an end over the first gate dielectric layer;
forming a second gate dielectric layer over the end of the first polysilicon gate body layer, wherein the second gate dielectric layer is thicker than the first gate dielectric layer;
forming a second polysilicon gate body layer over the second gate dielectric layer over the end of the first polysilicon gate body layer;
forming a split gate field plate from the second polysilicon gate body layer over the second gate dielectric layer over the end of the first polysilicon gate body layer; and
forming a source region and a drain region configured for a laterally-diffused metal-oxide semiconductor (LDMOS) transistor in the semiconductor substrate,
wherein the split gate field plate has a tapered surface that is thinner toward the drain region.
